(19) United States
(12) Patent Application Publication
(10) Pub. No.: US 2009/0102056 A1
(43) Pub. Date: Apr. 23, 2009

(54) Patterned Leads For WLCSP And Method For Fabricating The Same

(75) Inventors: Guoping Yu, SuZhou Industrial Park (CN); Guoqing Yu, SuZhou Industrial Park (CN); Qinqin Xu, SuZhou Industrial Park (CN); Wenlong Wang, SuZhou Industrial Park (CN); Wei Wang, SuZhou Industrial Park (CN)

Correspondence Address: ALLEN, DYER, DOPPELT, MILBRATH & GILCHRIST P.A., 1401 CITRUS CENTER 255 SOUTH ORANGE AVENUE, P.O. BOX 3791, ORLANDO, FL, 32802-3791, US

(73) Assignee: China Wafer Level CSP Ltd., SuZhou Industrial Park (CN)

(21) Appl. No.: 12/135,331

(22) Filed: Jun. 9, 2008

(30) Foreign Application Priority Data
Oct. 18, 2007 (CN) 200710134026.5

(51) Int. Cl. H01L 23/48; H01L 21/60

(52) U.S. Cl. 257/773; 438/113; 257/E21.502; 257/E23.01

(57) ABSTRACT

The present invention provides patterned leads for a wafer level chip size package and methods for fabricating the same. The patterned leads include connection leads and solder pads. In designing, a compensation pattern is disposed on the connection lead or on the solder pad, so as to increase the distance between the connection lead and the solder pad. The present invention meets a tendency of increasing quantity per area of peripheral arrayed compatible pads and solder bumps on a semiconductor chip, and also saves more space for layout of leads on the chip bottom surface so as to avoid potential short circuit in between which happens in increasing probability with increasing quantity per area on the condition of the lead and the solder bump.

### CROSS-REFERENCE TO RELATED APPLICATIONS

The present invention claims priority from Chinese Patent Application Ser. No. 200710134026.5 filed Oct. 18, 2007, entitled “Patterned Leads for WLCSP and Method for Fabricating the Same” by Yu et al., which is incorporated herein by reference for all purposes.

### FIELD OF THE INVENTION

The present invention relates generally to lead pattern design and making technology, and more particularly to patterned leads for wafer level chip size package (WLCSP) and methods for fabricating the same.

### BACKGROUND OF THE INVENTION

With the miniaturization of electronic devices and increase of circuit density in semiconductor industry, technology of chip size package (CSP) is now under great development, of which the package size is similar to the semiconductor chip encased therein.

Conventional packaging technologies, such as wire bonding, tape automatic bonding (TAB) and flip chip, have their own disadvantages. In wire bonding and TAB, a semiconductor package has a footprint much larger than that of the original chip. Flip chip package involves a direct electrical connection of face down electronic components onto substrates/carriers via conductive solder ball bumps of the chip. The flip-chip package encounters a problem, namely, cracking of solder ball bump joint due to large thermal expansion mismatch between a wafer and a substrate. Chip size package is manufactured either in the form of individual chips diced from a wafer, or in a wafer form and then the individual chip size packages are singulated from the wafer. The latter is referred to as a wafer level chip size package (hereinafter WLCSP).

For WLCSP, generally a plurality of compatible pads formed in a peripheral arrayed type on semiconductor chips are redistributed through conventional redistribution processes involving a redistribution layer into a plurality of metal pads, sometimes called solder bumps, in an area array type. Solder bumps on the WLCSP surface are larger in diameter and arranged farther apart from each other, thus a WLCSP print circuit board assembly is more robust. Compared with other types of package, WLCSP has better electrical conductivity and costs lower in fabrication.

FIG. 1 shows a typical cross-section of a ShellOC packaged chip device with a layer of prior art lead pattern. The processes for fabricating the ShellOC packaged chip device with prior art lead pattern are as follows:

As shown in FIG. 2A, on a first glass 5, cavity walls 10 are formed by means of photolithography technique.

As shown in FIG. 2B, with the aid of a high-temperature epoxy, the glass 5 with cavity walls 10 formed thereon is applied to cover the silicon chip 20 with optical or image sensors at its center and a plurality of compatible pads disposed at the periphery of each of the chips, wherein an optical or imaging component (as shadowed at the center) is encased within a cavity, thereby preventing the optical/imaging component from being contaminated by outside environment.

As shown in FIG. 2C, the chip 20 is first thinned at its non-active surface by using mechanical grinding and plasma technique in sequence, and further selectively etched by means of photolithography and plasma techniques, thus a portion of compatible pads 15 being exposed through trench formation therein.

As shown in FIG. 2D, an insulating material 25, e.g., epoxy, is employed to fully fill the trench and therefore covers the silicon slope and the exposed compatible pads 15. Afterwards, a second glass 30 is bonded to the silicon chip 20.

As shown in FIG. 2E, an insulating material 35, solder mask, is coated on the glass 30 as a mechanical buffer layer for later notching.

Next, as shown in FIG. 2F, metal deposition 40 instead of notching in the standard process flow is conducted with sputtering deposition technique.

For the following package steps, a light sensitive solder mask 45 is coated on the metal layer 40, and BGA 50 printing are carried out in turn.

FIG. 3 shows the layer of prior art lead pattern on the ShellOC packaged chip device as shown in FIG. 1. Leads 35 are deposited on the substrate. Leads 35 connect solder pads 55 and compatible pads 15. The solder bumps 50 will be printed on the solder pads. The size of a chip is partly determined by space between solder bumps 50. Decreasing space between solder bumps 50 can decrease chip size.

FIG. 4 is an enlarged view of partial prior art lead pattern as shown in FIG. 3. After sputtering, the pattern of lead 35 and solder pad 55 will be transformed from mask to substrate. The pattern is formed on the substrate by deposited metal.

There are some limits in designing leads 35 and solder pads 55. In designing, sizes of solder bumps, locations of leads, sizes of leads and locations of solder bumps are determined. The shrink of space will increase the risk of the short circuit. So it should be improved when the chip size needs to be changed smaller.

### SUMMARY OF THE INVENTION

The present invention aims to provide patterned leads for WLCSP and methods for fabricating the same, so as to effectively overcome the difficulties in lead making and greatly reduce the possibility of short circuit.

According to one embodiment of the present invention, patterned leads for wafer level chip size package is provided, comprising connection leads and solder pads, wherein a compensation pattern is disposed on at least one of the connection leads so as to increase the distance between the connection lead and an adjacent solder pad on a same plane.

Wherein, the compensation pattern on the connection lead is located directly facing the adjacent solder pad.

Wherein, the compensation pattern on the connection lead is a concave arc pattern, a concave trapezoid pattern or a concave rectangle pattern, or any combination thereof.

According to another embodiment of the present invention, patterned leads for wafer level chip size package is provided, comprising connection leads and solder pads, wherein a compensation pattern is disposed on at least one of the solder pads so as to increase the distance between the solder pad and an adjacent connection lead on a same plane.

Wherein, the compensation pattern on the solder pad is a chord line pattern.

Wherein, the chord line of the compensation pattern is parallel to the adjacent connection lead.

According to another embodiment of the present invention, patterned leads for wafer level chip size package is provided, comprising connection leads and solder pads, wherein at least one of the solder pads is in the shape of an ellipse so as to increase the distance between the solder pad and an adjacent connection lead on the same plane.

Wherein, the ellipse shaped solder pad has its long axis parallel to the adjacent connection lead.

The present invention further provides a method for fabricating wafer level chip size package, comprising following steps:

providing a substrate wafer having formed thereon silicon chips, with a plurality of compatible pads disposed at the periphery of each of the chips on said substrate wafer;

forming a first insulating layer over the non-active surface of the substrate wafer, while leaving portions of the compatible pads exposed;

forming patterned leads of the present invention over portions of the first insulating layer and the exposed compatible pads;

forming a second insulating layer on the patterned leads, while leaving portions of the patterned leads exposed;

forming solder bumps on exposed portions of the patterned leads, each solder bump corresponding to a compatible pad;

dicing the substrate wafer to singulate the silicon chips therefrom.

Wherein, the patterned leads are made of metal material of Copper or Nickel, and the thickness of the patterned leads is 1˜10 um.

The present invention has successfully overcome the difficulties in lead pattern design and making caused by short distance, meanwhile it enables the design distance between solder bumps to be reduced. Therefore, the present invention has notable social and economic effects with a promising prospect.

### BRIEF DESCRIPTION OF THE DRAWINGS

Hereinafter, the present invention will be further described in details in combination with the accompanying drawings and the preferred embodiments.

FIG. 1 is a typical cross-section view of a WLCSP chip device with a layer of prior art lead pattern;

FIG. 2A to 2F shows a schematic process for fabricating the wafer packaged chip device as shown in FIG. 1.

FIG. 3 is a schematic view of the layer of prior art lead pattern on the WLCSP chip device as shown in FIG. 1;

FIG. 4 is an enlarged view of partial prior art lead pattern as shown in FIG. 3;

FIG. 5 shows partial lead pattern with a concave arc shaped compensation pattern on the connection lead according to one embodiment of the present invention;

FIG. 6 shows partial lead pattern with a concave trapezoid shaped compensation pattern on the connection lead according to one embodiment of the present invention;

FIG. 7 shows partial lead pattern with a concave rectangle shaped compensation pattern on the connection lead according to one embodiment of the present invention;

FIG. 8 shows partial lead pattern with a chord line shaped compensation pattern on the solder pad according to one embodiment of the present invention; and

FIG. 9 shows partial lead pattern with an ellipse shaped solder pad according to one embodiment of the present invention.

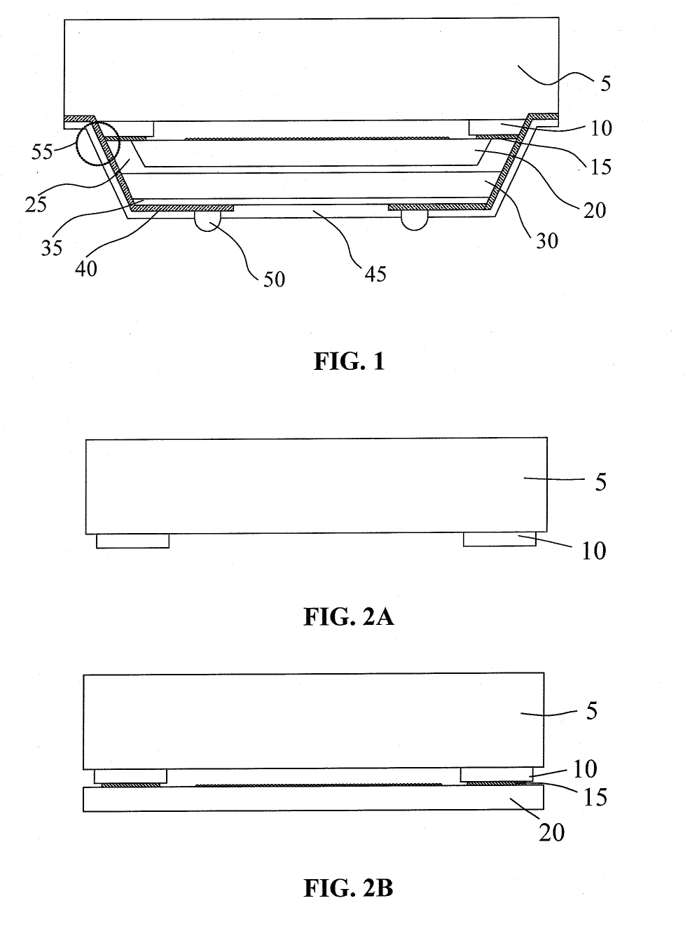

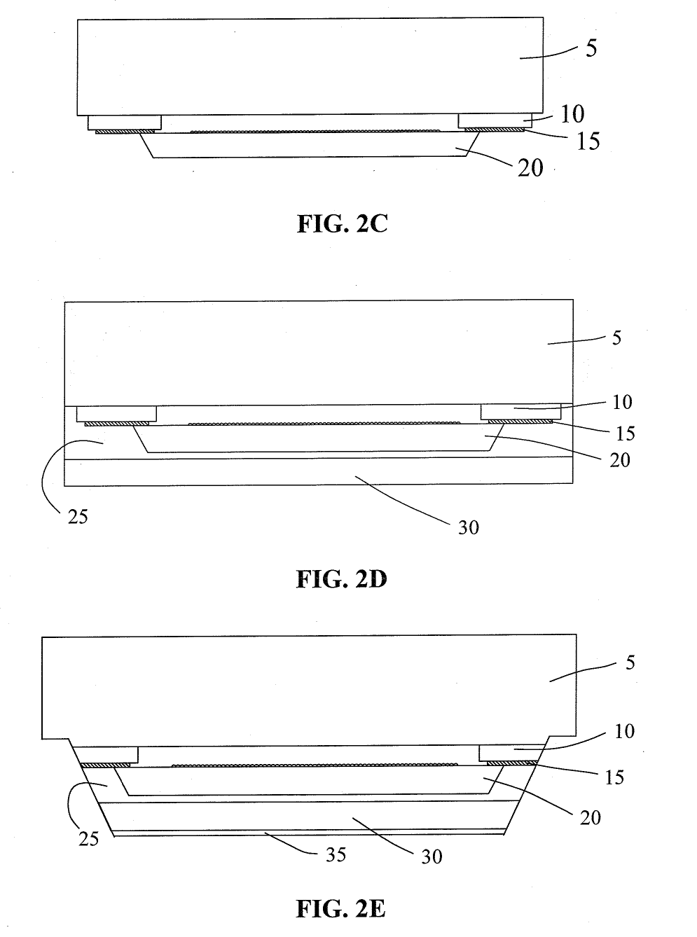

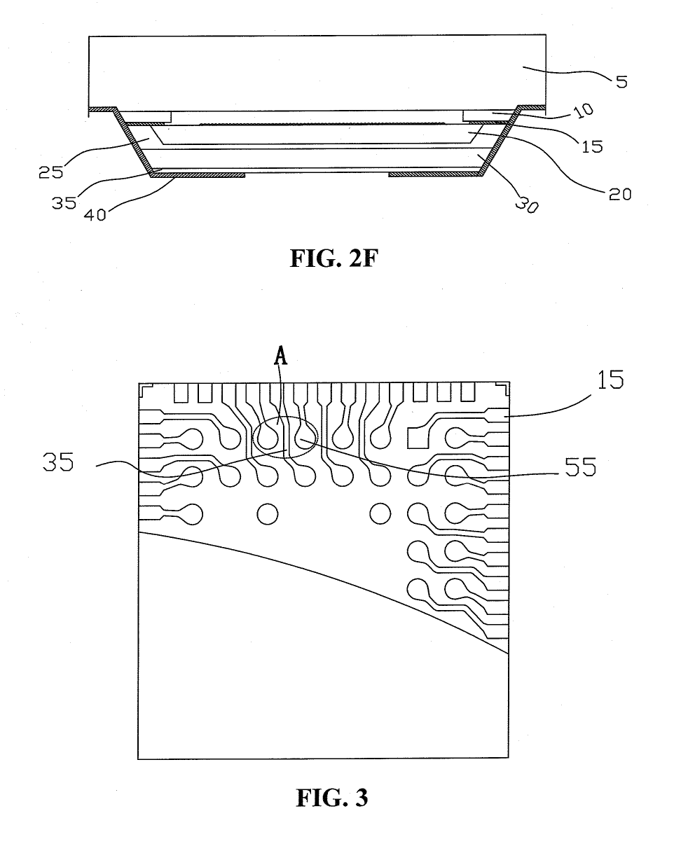

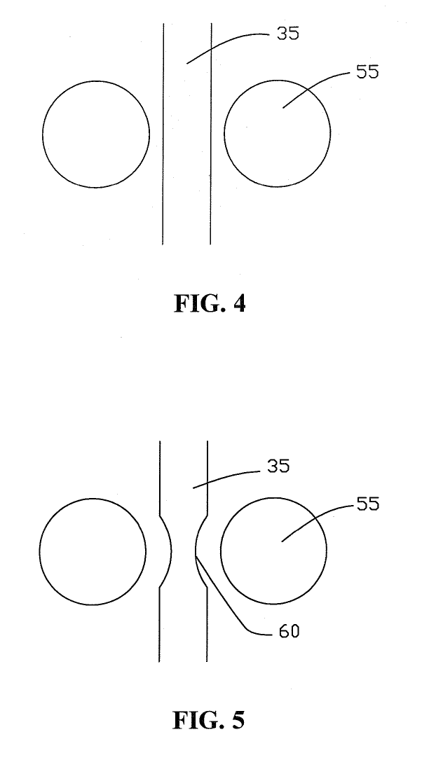

In the figures, the reference numeral 5 denotes glass, the numeral 15 denotes a compatible pad, the numeral 20 denotes a chip body, the numeral 30 denotes a solder bump, the numeral 35 denotes a connection lead, the numeral 40 denotes a bottom substrate, the numeral 55 denotes a solder pad, the numeral 60 denotes a concave arc pattern of the connection lead, the numeral 65 denotes a concave trapezoid pattern, the numeral 70 denotes a concave rectangle pattern, the numeral 75 denotes a chord line pattern of the solder pad, the numeral 80 denotes an ellipse shaped solder pad.

### DETAILED DESCRIPTION OF EXEMPLARY EMBODIMENTS

It should be pointed out that all figures in the present invention are not drawn in exact proportion. Wherever possible, the same reference numbers are used in the drawings and the description to refer to the same or like parts.

According to present invention, in designing, if the distance between a connection lead 35 and a solder pad 55 is too small, that is, less than the minimum distance required in design norm, a compensation pattern is designed on the original lead pattern.

As shown in FIG. 5, according to one embodiment of the present invention, on the connection lead 35 at a location directly facing the solder pad 55, a compensation pattern in the shape of a concave arc 60 is designed to increase the distance between the connection lead 35 and the solder pad 55, so as to meet the design norm.

Certainly, other compensation patterns can be designed to meet different requirements.

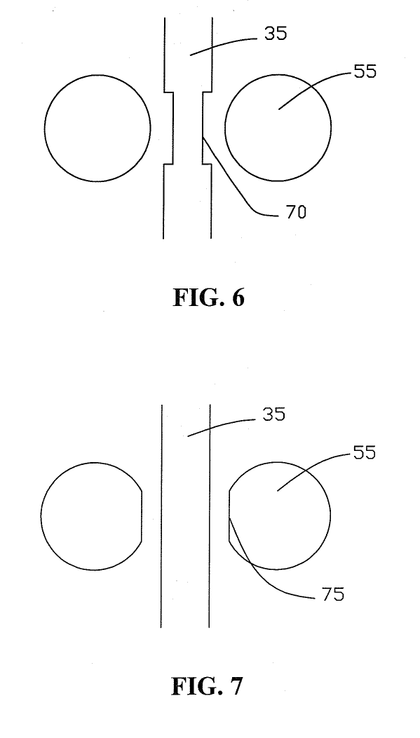

As shown in FIG. 6, according to one embodiment of the present invention, on the connection lead 35 at a location directly facing the solder pad 55, a compensation pattern in the shape of a concave trapezoid 65 is designed to increase the distance between the connection lead 35 and the solder pad 55.

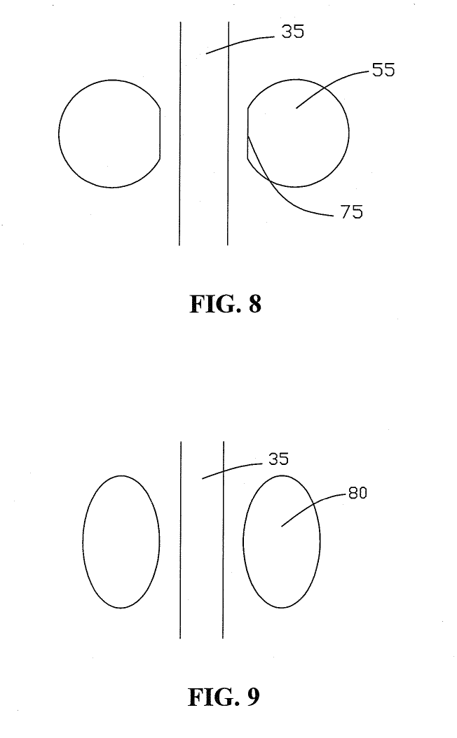

As shown in FIG. 7, according to one embodiment of the present invention, on the connection lead 35 at a location directly facing the solder pad 55, a compensation pattern in the shape of a concave rectangle pattern 70 is designed to increase the distance between the connection lead 35 and the solder pad 55.

The advantages lie in that, even if the distance between the solder pad 55 and the connection lead 35 is reduced, the solder pad 55 and the connection lead 35 can still keep apart sufficiently, which will not bring difficulties to lead pattern making or negatively affect the lead performance.

Alternatively, without changing the pattern of the connection leads 35, a compensation pattern may be designed on the solder pad 55. Similarly, even if the distance between the solder pad 55 and the connection lead 35 is reduced, the solder pad 55 and the connection lead 35 can still keep apart sufficiently, which will not bring difficulties to lead pattern making or negatively affect the lead performance.

As shown in FIG. 8, according to one embodiment of the present invention, on the solder pad 55, a compensation pattern in the shape of a chord line pattern 75 is designed to increase the distance between the connection lead 35 and the solder pad 55, wherein the chord line of the compensation pattern is parallel to the connection lead 35.

As shown in FIG. 9, according to one embodiment of the present invention, the solder pad 55 is in the shape of an ellipse with its long axis parallel to the connection lead 35 to increase the distance between the connection lead 35 and the solder pad 55.

The method for fabricating wafer level chip size package with patterned leads of the present invention comprises following steps:

providing a substrate wafer having formed thereon silicon chips, with a plurality of compatible pads disposed at the periphery of each of the chips on said substrate wafer;

forming a first insulating layer over the non-active surface of the substrate wafer, while leaving portions of the compatible pads exposed;

forming patterned leads of the present invention over portions of the first insulating layer and the exposed compatible pads;

forming a second insulating layer on the patterned leads, while leaving portions of the patterned leads exposed;

forming solder bumps on exposed portions of the patterned leads, each solder bump corresponding to a compatible pad;

dicing the substrate wafer to singulate the silicon chips therefrom.

The patterned leads are made of a metal material of Copper or Nickel, and the thickness of the patterned leads is 1˜10 um.

It should be noted that the present invention is not limited to the above embodiments, but applicable for any of ShellOC, ShellOP and ShellUT packages or any modification thereof.

Although this invention has been described in connection with specific forms and embodiments thereof, it will be appreciated that various modifications may be made from the specific details described here in without departing form the spirit or scope of the invention as set forth in the appended claims.

What is claimed is:

1. Patterned leads for wafer level chip size package, comprising connection leads and solder pads, wherein a compensation pattern is disposed on at least one of the connection leads so as to increase the distance between the connection lead and an adjacent solder pad on a same plane.

2. Patterned leads for wafer level chip size package as claimed in claim 1, wherein the compensation pattern on the connection lead is located directly facing the adjacent solder pad.

3. Patterned leads for wafer level chip size package as claimed in claim 1, wherein the compensation pattern on the connection lead is a concave arc pattern, a concave trapezoid pattern or a concave rectangle pattern, or any combination thereof.

4. Patterned leads for wafer level chip size package as claimed in claim 2, wherein the compensation pattern on the connection lead is a concave arc pattern, a concave trapezoid pattern or a concave rectangle pattern, or any combination thereof.

5. A method for fabricating wafer level chip size package, comprising following steps:
providing a substrate wafer having formed thereon silicon chips, with a plurality of compatible pads disposed at the periphery of each of the chips on said substrate wafer;
forming a first insulating layer over the non-active surface of the substrate wafer, while leaving portions of the compatible pads exposed;
forming patterned leads as claimed in claim 1 over portions of the first insulating layer and the exposed compatible pads;
forming a second insulating layer on the patterned leads, while leaving portions of the patterned leads exposed;
forming solder bumps on exposed portions of the patterned leads, each solder bump corresponding to a compatible pad;
dicing the substrate wafer to singulate the silicon chips therefrom.

6. A method for fabricating wafer level chip size package, comprising following steps:
providing a substrate wafer having formed thereon silicon chips, with a plurality of compatible pads disposed at the periphery of each of the chips on said substrate wafer;
forming a first insulating layer over the non-active surface of the substrate wafer, while leaving portions of the compatible pads exposed;
forming patterned leads as claimed in claim 4 over portions of the first insulating layer and the exposed compatible pads;
forming a second insulating layer on the patterned leads, while leaving portions of the patterned leads exposed;
forming solder bumps on exposed portions of the patterned leads, each solder bump corresponding to a compatible pad;
dicing the substrate wafer to singulate the silicon chips therefrom.

7. The method for fabricating wafer level chip size package as claimed in claim 6, wherein the patterned leads are made of metal material of Copper or Nickel.

8. The method for fabricating wafer level chip size package as claimed in claim 6, wherein the thickness of the patterned leads is 1˜10 um.

9. Patterned leads for wafer level chip size package, comprising connection leads and solder pads, wherein a compensation pattern is disposed on at least one of the solder pads so as to increase the distance between the solder pad and an adjacent connection lead on a same plane.

10. Patterned leads for wafer level chip size package as claimed in claim 9, wherein the compensation pattern on the solder pad is a chord line pattern.

11. Patterned leads for wafer level chip size package as claimed in claim 10, wherein the chord line of the compensation pattern is parallel to the connection lead.

12. A method for fabricating wafer level chip size package, comprising following steps:
providing a substrate wafer having formed thereon silicon chips, with a plurality of compatible pads disposed at the periphery of each of the chips on said substrate wafer;
forming a first insulating layer over the non-active surface of the substrate wafer, while leaving portions of the compatible pads exposed;
forming patterned leads as claimed in claim 9 over portions of the first insulating layer and the exposed compatible pads;
forming a second insulating layer on the patterned leads, while leaving portions of the patterned leads exposed;
forming solder bumps on exposed portions of the patterned leads, each solder bump corresponding to a compatible pad;
dicing the substrate wafer to singulate the silicon chips therefrom.

13. A method for fabricating wafer level chip size package, comprising following steps:
providing a substrate wafer having formed thereon silicon chips, with a plurality of compatible pads disposed at the periphery of each of the chips on said substrate wafer;
forming a first insulating layer over the non-active surface of the substrate wafer, while leaving portions of the compatible pads exposed;
forming patterned leads as claimed in claim 11 over portions of the first insulating layer and the exposed compatible pads;
forming a second insulating layer on the patterned leads, while leaving portions of the patterned leads exposed;
forming solder bumps on exposed portions of the patterned leads, each solder bump corresponding to a compatible pad;
dicing the substrate wafer to singulate the silicon chips therefrom.

14. The method for fabricating wafer level chip size package as claimed in claim 13, wherein the patterned leads are made of metal material of Copper or Nickel.

15. The method for fabricating wafer level chip size package as claimed in claim 13, wherein the thickness of the patterned leads is 1˜10 um.

16. Patterned leads for wafer level chip size package, comprising connection leads and solder pads, wherein at least one of the solder pads is in the shape of an ellipse so as to increase the distance between the solder pad and an adjacent connection lead on a same plane.

17. Patterned leads for wafer level chip size package as claimed in claim 16, wherein the ellipse shaped solder pad has its long axis parallel to the adjacent connection lead.

18. A method for fabricating wafer level chip size package, comprising following steps:
providing a substrate wafer having formed thereon silicon chips, with a plurality of compatible pads disposed at the periphery of each of the chips on said substrate wafer;
forming a first insulating layer over the non-active surface of the substrate wafer, while leaving portions of the compatible pads exposed;
forming patterned leads as claimed in claim 17 over portions of the first insulating layer and the exposed compatible pads;
forming a second insulating layer on the patterned leads, while leaving portions of the patterned leads exposed;
forming solder bumps on exposed portions of the patterned leads, each solder bump corresponding to a compatible pad;
dicing the substrate wafer to singulate the silicon chips therefrom.

19. The method for fabricating wafer level chip size package as claimed in claim 18, wherein the patterned leads are made of metal material of Copper or Nickel.

20. The method for fabricating wafer level chip size package as claimed in claim 18, wherein the thickness of the patterned leads is 1˜10 um.
